(19) United States
(12) Patent Application Publication
(10) Pub. No.: US 2019/0152774 A1
(43) Pub. Date: May 23, 2019

(54) MEMS SENSOR AND METHOD FOR MANUFACTURING SAME

(71) Applicant: SHIN SUNG C&T CO., LTD., Seoul (KR)

(72) Inventors: Ci Moo SONG, Yongin-si, Gyeonggi-do (KR); Keun Jung YOUN, Dong-gu, Incheon (KR); Do Hyeon LEE, Seoul (KR); Yong Kook KIM, Seoul (KR); Jae Hyun AHN, Seoul (KR)

(73) Assignee: SHIN SUNG C&T CO., LTD., Seoul (KR)

(21) Appl. No.: 16/256,464

(22) Filed: Jan. 24, 2019

Related U.S. Application Data
(63) Continuation of application No. PCT/KR2017/003961, filed on Apr. 12, 2017.

(30) Foreign Application Priority Data
Jul. 26, 2016 (KR) 10-2016-0095022

(51) Int. Cl. B81C 1/00; G01P 15/125; G01P 15/14; B81B 7/00

(52) U.S. Cl. CPC B81C 1/00301; G01P 15/125; G01P 15/14; B81C 1/00063; B81B 2201/0242; B81C 1/00047; B81B 7/0006; B81B 2201/0235; B81C 1/00095

(57) ABSTRACT

The MEMS sensor includes: a device substrate on which a device pattern is formed; a cap substrate disposed on top of the device substrate, the cap substrate comprising a first cavity area; a base substrate disposed on the bottom of the device substrate; a first-through silicon via formed through the base substrate, the first-through silicon via including a first core area for outputting an electrical signal provided from the device pattern to the outside or transmitting an electrical signal provided from the outside to the device pattern, a first insulating area surrounding an outer surface of the first core area, a first peripheral area surrounding an outer surface of the first insulating area, and a second insulating area surrounding an outer surface of the first peripheral area; and a circuit board, electrically connected to the first-through silicon via, for processing electrical signals for the device pattern.

### CROSS-REFERENCE TO RELATED APPLICATION

This application is a continuation of International Patent Application No. PCT/KR2017/003961, filed Apr. 12, 2017, now pending, which claims foreign priority from Korean Patent Application No. 10-2016-0095022, filed on Jul. 26, 2016 in the Korean Intellectual Property Office, the disclosure of each document is incorporated herein by reference in their entirety.

### TECHNICAL FIELD

The present invention relates to a microelectromechanical systems (MEMS) sensor and a manufacturing method thereof.

### BACKGROUND ART

Microelectromechanical systems (MEMS) is a technology for implementing mechanical and electrical components using semiconductor processes. A representative example of a device using the MEMS technology is a MEMS gyroscope for measuring an angular velocity and a MEMS acceleration sensor for measuring an acceleration. Generally, a spatial motion of an object may be described as a 3-degrees-of-freedom (DOF) rotational movement and a 3-DOF linear movement. The 3-DOF rotational movement may be sensed by x-, y-, and z-axis gyroscopes, and the 3-DOF linear movement may be sensed by x-, y-, and z-axis acceleration sensors.

A gyroscope measures an angular velocity by measuring the Coriolis force generated when a rotational angular velocity is applied to an object moving at a predetermined speed. In this case, the Coriolis force is proportional to a cross product between the moving velocity and the rotational angular velocity caused by an external force.

Also, in order to sense the generated Coriolis force, the gyroscope has a vibrating mass therein. Typically, a direction in which the mass in the gyroscope is driven is referred to as a driving direction, a direction in which a rotational angular velocity is applied to the gyroscope is referred to as an input direction, and a direction in which the Coriolis force generated in the mass is sensed is referred to as a sensing direction. The driving direction, the input direction, and the sensing direction are set to be spatially perpendicular to each other. Typically, gyroscopes using the MEMS technology are classified into x-axis (y-axis) gyroscopes and z-axis gyroscopes when a bottom wafer substrate is considered as an xy plane.

Unlike gyroscopes, acceleration sensors have a structure capable of measuring an acceleration by sensing a mass displacement caused by external acceleration directly acting on the mass without needing to be artificially driven. Thus, the acceleration sensors have a simpler structure than the gyroscopes. MEMS acceleration sensors may be classified into x-axis or y-axis acceleration sensors and z-axis acceleration sensors which are capable of sensing accelerations in two axial directions parallel to a plane of the bottom wafer substrate. An x-axis acceleration sensor may be defined as an acceleration sensor with an input direction parallel to the plane, and a y-axis acceleration sensor may be defined as an acceleration sensor in a direction perpendicular to the x axis on the plane. However, the y-axis acceleration sensor is the same as the x-axis acceleration sensor in terms of principle except that the y-axis acceleration sensor has a different housing installation direction from the x-axis acceleration sensor. Accordingly, the x-axis acceleration sensor and the y-axis acceleration sensor are collectively referred to as an xy-axis acceleration sensor.

In the case of such an xy-axis acceleration sensor, a sensor mass is capable of sensing a vibrating movement in a plane. Thus, the xy-axis acceleration sensor has a structure of placing the sensor mass to be parallel to the bottom wafer substrate and of sensing the movement using a sensing electrode formed in a direction parallel to the bottom wafer substrate. Unlike this, the z-axis acceleration sensor should sense a movement vertical to the bottom wafer substrate, and thus it is difficult to implement the z-axis acceleration sensor by vertically placing the sensor mass and the sensing electrode due to characteristics of MEMS devices manufactured by stacking wafers.

Accordingly, there is known a z-axis MEMS acceleration sensor that senses an acceleration in a z-axis direction vertical to the xy plane by using pivotal movement of the sensor mass with respect to one rotary support shaft. Such a z-axis MEMS acceleration sensor is composed of a fastening anchor, a rotary support shaft that provides torsional rigidity, and a sensor mass pivotable with respect to the rotary support shaft.

In this case, a MEMS acceleration sensor may be separately provided for each axis, but it is possible to want to measure accelerations for all three axes. To this end, there is known an integrated 3-axis acceleration sensor.

### DETAILED DESCRIPTION OF THE INVENTION

### Technical Problem

It is an objective of the present invention to provide a MEMS sensor having greatly reduced parasitic noise and enhanced operation performance.

It is another objective of the present invention to provide a method of manufacturing a MEMS sensor having greatly reduced parasitic noise and enhanced operation performance.

It should be noted that objectives of the present invention are not limited to the above-described objectives, and other objectives that are not described herein will be apparent to those skilled in the art from the following descriptions.

### Technical Solution

According to an aspect of the present invention, there is provided a microelectromechanical systems (MEMS) sensor including a device substrate on which a device pattern is formed; a cap substrate disposed above the device substrate, the cap substrate including a first cavity area; a base substrate disposed below the device substrate; a first through-silicon via formed through the base substrate, the first through-silicon via including a first core area for outputting an electric signal provided from the device pattern to the outside or transmitting an electric signal provided from the outside to the device pattern, a first insulating area surrounding an outer surface of the first core area, a first peripheral area surrounding an outer surface of the first insulating area, and a second insulating area surrounding an outer surface of the first peripheral area; and a circuit board electrically connected to the first through-silicon via to process electric signals for the device pattern.

According to another aspect of the present invention, there is provided a method of manufacturing a microelectromechanical systems (MEMS) sensor, the method including doping a base substrate; forming, in the base substrate, a first annular trench, a second annular trench surrounding the first annular trench, a first core area defined by the first annular trench, and a first peripheral area defined by the first annular trench and the second annular trench; forming a first insulating area and a second insulating area by filling the first annular trench and the second annular trench with an insulating material, respectively; and polishing a lower surface of the base substrate and separating the first core area from the first peripheral area to form a first through-silicon via including the first core area, the first insulating area, the first peripheral area, and the second insulating area.

Other specific details of the present invention are included in the detailed description and drawings.

### Advantageous Effects of the Invention

With the MEMS sensor according to some embodiments of the present invention, it is possible to significantly decrease parasitic signal noise that is inevitably generated by a structure of a through-silicon via (TSV) passing through a substrate. Also, with the method of manufacturing the MEMS sensor according to some embodiments of the present invention, it is possible to manufacture a MEMS sensor having greatly reduced parasitic signal noise through a simple additional process. The reduction in the parasitic noise may significantly improve a signal-to-noise ratio (SNR) to increase the precision and operation speed of the MEMS sensor.

### DESCRIPTION OF THE DRAWINGS

FIGS. 1 and 2 are side-sectional views for describing a microelectromechanical systems (MEMS) sensor according to some embodiments of the present invention.

FIG. 3 is a layout diagram for describing an acceleration MEMS sensor according to some embodiments of the present invention.

FIG. 4 is a layout diagram for describing a gyro MEMS sensor according to some embodiments of the present invention.

FIG. 5 is a plane-sectional view for describing a through-silicon via (TSV) of FIGS. 1 and 2 in detail.

FIG. 6 is an equivalent circuit diagram for describing the TSV of FIG. 5 in detail.

FIG. 7 is a plane-sectional view for describing a TSV of a MEMS sensor according to some embodiments of the present invention.

FIG. 8 is an equivalent circuit diagram for describing the TSV of FIG. 7 in detail.

FIG. 9 is a plane-sectional view for describing a TSV of a MEMS sensor according to some embodiments of the present invention.

FIG. 10 is a plane-sectional view for describing a TSV of a MEMS sensor according to some embodiments of the present invention.

FIG. 11 is a plane-sectional view for describing a TSV of a MEMS sensor according to some embodiments of the present invention.

FIG. 12 is a plane-sectional view for describing a TSV of a MEMS sensor according to some embodiments of the present invention.

FIGS. 13 to 17 are intermediate views for describing a method of manufacturing a MEMS sensor according to some embodiments of the present invention.

FIGS. 18 to 21 are intermediate views for describing a method of manufacturing a MEMS sensor according to some embodiments of the present invention.

### MODE OF THE INVENTION

Advantages and features of the present invention and implementation methods thereof will be clarified through following embodiments described with reference to the accompanying drawings. The invention may, however, be embodied in different forms and should not be construed as limited to the embodiments set forth herein. Rather, these embodiments are provided so that this disclosure will be thorough and complete, and will fully convey the scope of the present invention to those skilled in the art. Therefore, the scope of the invention is defined only by the appended claims. Like reference numerals refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. As used herein, the term “and/or” includes any and all combinations of one or more of the associated listed items.

It will be understood that when an element is referred to as being “on” another element, it can be directly on the other element or intervening elements may be present therebetween. In contrast, when an element is referred to as being “directly on” another element, there are no intervening elements present therebetween.

Spatially relative terms, such as “below,” “beneath,” “lower,” “above,” “upper,” “on,” “between,” and the like, may be used herein for ease of description to describe the relationship of one element to another element(s) as illustrated in the figures. It will be understood that the spatially relative terms are intended to encompass different orientations of a device in use or operation, in addition to the orientation depicted in the figures. For example, when a device shown in one of the figures is turned over, elements described as “below” or “beneath” other elements would then be oriented “above” the other elements. Thus, the exemplary term “below” or “beneath” may encompass both orientations of “above” and “below.” The element may be otherwise oriented, and the spatially relative descriptors used herein may be interpreted accordingly.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Although the terms first, second, etc. may be used herein to describe various elements, it will be appreciated that these elements should not be limited by these terms. These terms are used only to distinguish one element from another element. Thus, it will be appreciated that a first element discussed below could be termed a second element without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

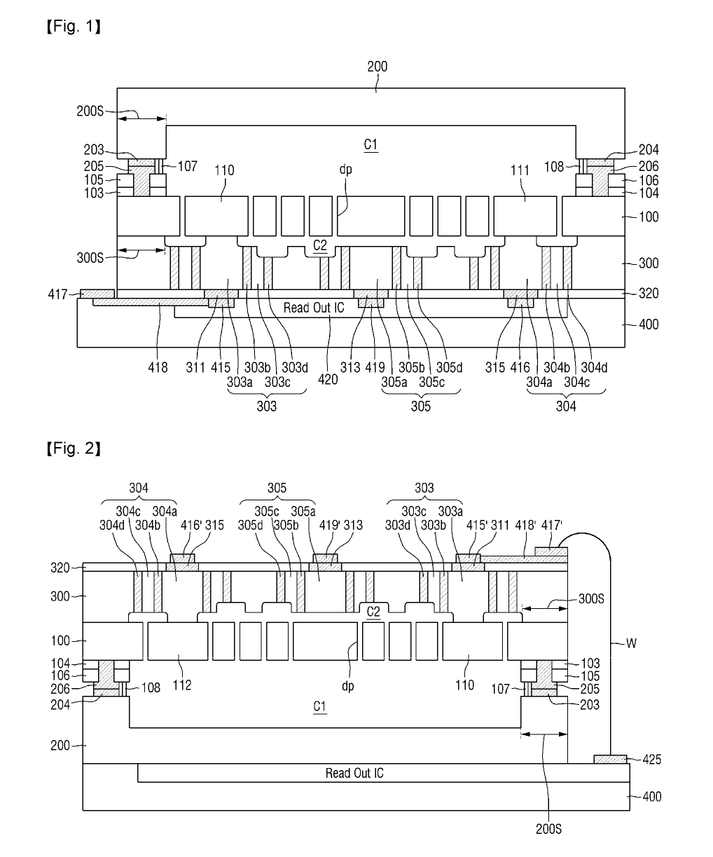

Hereinafter, a microelectromechanical systems (MEMS) sensor according to some embodiments of the present invention will be described with reference to FIGS. 1 to 6.

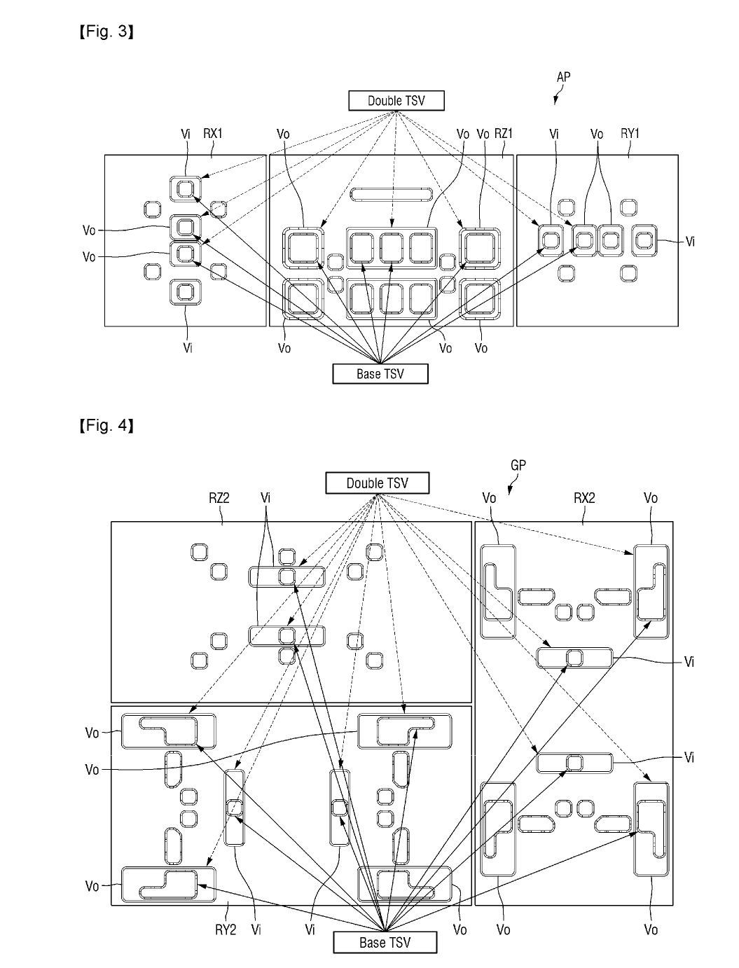

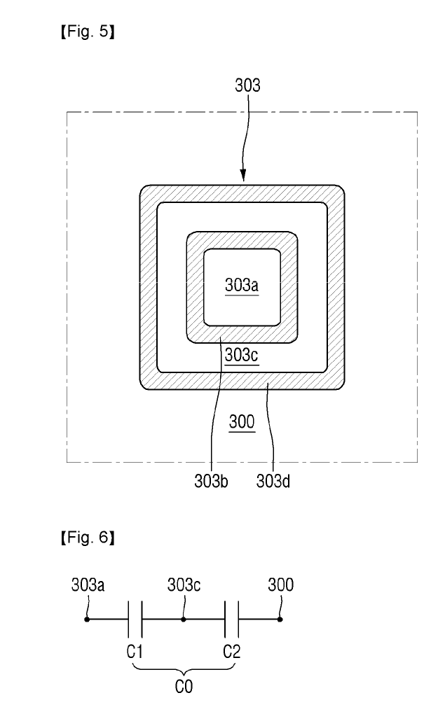

FIGS. 1 and 2 are side-sectional views for describing the MEMS sensor according to some embodiments of the present invention, and FIG. 3 is a layout diagram for describing an acceleration MEMS sensor according to some embodiments of the present invention. FIG. 4 is a layout diagram for describing a gyro MEMS sensor according to some embodiments of the present invention, and FIG. 5 is a plane-sectional view for describing a TSV of FIGS. 1 and 2 in detail. FIG. 6 is an equivalent circuit diagram for describing the TSV of FIG. 5 in detail.

Referring to FIG. 1, the MEMS sensor according to some embodiments of the present invention includes a device substrate 100, a cap substrate 200, a base substrate 300, and a circuit board 400.

A MEMS-based device pattern dp may be formed on the device substrate 100. The MEMS is generally referred to as a microelectromechanical system, microelectronic control technology, etc., and refers to a micrometer (μm) or millimeter (mm) scale micromachining process technology based on semiconductor processing technology. For example, the device pattern dp may be a MEMS-based xy-axis gyroscope or z-axis gyroscope. The device substrate 100 may be a silicon wafer having a low resistance of about 0.01 Ωcm, but the present invention is not limited thereto.

Passivation films 103 and 104 may be formed on the device substrate 100. A chemical vapor deposition (CVD) process, an atomic layer deposition (ALD) process, a physical vapor deposition (PVD) process, a plasma-enhanced CVD (PECVD) process, a low pressure CVD (LPCVD) process, a pulsed CVD (P-CVD) process, or a combination thereof may be used as a deposition process for forming the passivation films 103 and 104.

In some embodiments of the present invention, a deposition gas may be supplied onto the device substrate 100 in order to form passivation films 103 and 104, which are made of a metal nitride film containing Ru and N, using a CVD or ALD process. The deposition gas may include a Ru precursor and a nitrogen source. A carrier gas (e.g., an inert gas), a reducing gas, or a combination thereof may be supplied together with the deposition gas.

For example, the Ru precursor includes, but is not limited to, Ru₃(CO)₁₂, Ru(DMPD)(tCp) ((2,4-dimethylpentadienyl)(ethylcyclopentadienyl)ruthenium), Ru(DMPD)₂(bis(2,4-dimethylpentadienyl)ruthenium), Ru(DMPD)(MeCp) (4-dimethylpentadienyl)(methylcyclopentadienyl)ruthenium), and Ru(EtCp)₂(bis(ethylcyclopentadienyl)ruthenium).

The nitrogen source may be selected from among, but not limited to, nitrogen (N₂) gas, nitrogen monoxide (NO) gas, dinitrogen monoxide (N₂O) gas, nitrogen dioxide (NO₂) gas, ammonia (NH₃) gas, N-containing radicals (e.g., N*, NH*, or NH₂*), amines, and a combination thereof.

In some embodiments, when N₂ is used as the nitrogen source, passivation films 103 and 104 which are made of ruthenium nitride may be obtained. In other embodiments, when NO₂ is used as the nitrogen source, passivation films 103 and 104 which are made of ruthenium oxynitride may be obtained.

Solder pads 105 and 106 may be formed on the passivation films 103 and 104, respectively. The solder pads 105 and 106 may be formed as a gold (Au) layer using an electrolytic plating method, but the present invention is not limited thereto. Solder contacts 205 and 206 may be formed on the solder pads 105 and 106, respectively, to electrically connect the cap substrate 200 thereabove and the device substrate 100 therebelow. In detail, metal pads 203 and 204 may be formed on the cap substrate 200 and brought into contact with the solder contacts 205 and 206, respectively to electrically connect the cap substrate 200 thereabove and the device substrate 100 therebelow. The metal pads 203 and 204 may be formed, for example, by performing electroplating on a seed layer.

The cap substrate 200 may be disposed above the device substrate 100, and a first cavity area C1 may be formed in the cap substrate 200. The cap substrate 200 may be mechanically connected to the device substrate 100 by a wafer-to-wafer bonding method. The first cavity area C1 may be a closed space formed by the cap substrate 200 and the device substrate 100 being bonded using the wafer-to-wafer bonding method.

The first cavity area C1 may be formed to have a step with respect to a surface of the cap substrate 200. That is, a portion of the surface of the cap substrate 200 may be etched to form an empty space, and the empty space may be the first cavity area C1. The first cavity area C1 is formed to correspond to an area in which the device pattern dp is formed on the device substrate 100 so that the first cavity area C1 serves to provide a space in which the device pattern dp can vibrate when the device pattern dp vibrates up, down, left, and right. For example, the device pattern dp may be an xy-axis gyroscope or a z-axis gyroscope, and such a device pattern dp may vibrate up, down, left, and right according to a user's movement.

One or more first cavity areas C1 may be formed. Since the device pattern dp formed on the device substrate 100 may have a complicated shape and a plurality of areas in which the device pattern dp vibrates may be present, the one or more first cavity areas C1 may be formed to correspond to positions at which the device pattern dp vibrates.

When a plurality of first cavity areas C1 are formed, the cavity areas may be separated from one another by a first sealing wall 200s formed by the cap substrate 200 and the device substrate 100.

Referring to FIG. 3, the device substrate 100 may be an acceleration MEMS sensor. The device substrate 100 may include an x-axis acceleration sensor area RX1, a y-axis acceleration sensor area RY1, and a z-axis acceleration sensor area RZ1. That is, the device substrate 100 may include a device pattern dp for a 3-axis acceleration sensor AP.

When the device substrate 100 is divided into three areas as shown in FIG. 3, the base substrate 300 overlapping the device substrate 100 may also be divided into three areas, that is, an x-axis acceleration sensor area RX1, a y-axis acceleration sensor area RY1, and a z-axis acceleration sensor area RZ1.

In the device substrate 100 and the base substrate 300, the x-axis acceleration sensor area RX1 may have the same shape as and be disposed perpendicularly to the y-axis acceleration sensor area RY1. The z-axis acceleration sensor area RZ1 may be shaped differently from those of the x-axis acceleration sensor area RX1 and the y-axis acceleration sensor area RY1.

Referring to FIG. 4, the device substrate 100 may be a gyro MEMS sensor. The device substrate 100 may include an x-axis gyro sensor area RX2, a y-axis gyro sensor area RY2, and a z-axis gyro sensor area RZ2. That is, the device substrate 100 may include a device pattern dp for a 3-axis gyro sensor GP.

When the device substrate 100 is divided into three areas as shown in FIG. 4, the base substrate 300, which overlaps the device substrate 100, may also be divided into three areas, that is, an x-axis gyro sensor area RX2, a y-axis gyro sensor area RY2, and a z-axis gyro sensor area RZ2.

In the device substrate 100 and the base substrate 300, the x-axis gyro sensor area RX2 may have the same shape as and be disposed perpendicularly to the y-axis gyro sensor area RY2. The z-axis gyro sensor area RZ2 may be shaped differently from those of the x-axis gyro sensor area RX2 and the y-axis gyro sensor area RY2.

Unlike FIGS. 3 and 4, the device substrate 100 may include a capacitive sensor structure other than the acceleration MEMS sensor and the gyro MEMS sensor. In such a capacitive sensor structure, a double through-silicon via (TSV) or a TSV with a three- or more-layered insulating area can reduce parasitic capacitance, thereby minimizing parasitic noise of electric signals and significantly improving operation performance.

In detail, for example, the capacitive sensor may be included in an actuator, a varactor, or the like. The capacitive sensor structure may be used in an electronic device such as a speaker.

Referring to FIG. 1 again, the base substrate 300 may be disposed below the device substrate 100, a second cavity area C2 may be formed in the base substrate 300, and first TSVs 303, 304, and 305 may be formed in the base substrate 300.

The first TSVs 303, 304, and 305 may serve to output an electric signal provided from the device pattern dp to the outside or transmit an electric signal provided from the outside to the device pattern dp. Further, first electrode pads 311, 313, and 315 may be formed on the first TSVs 303, 304, and 305, respectively, and the first electrode pads 311, 313, and 315 may be electrically connected to second electrode pads 415, 416, and 419, respectively.

The first electrode pads 311, 313, and 315 may be covered by a passivation film 320. The passivation film 320 may be made of an insulating material, and may provide electrical insulation such that the first electrode pads 311, 313, and 315 are prevented from being directly exposed to the outside except at points where the first electrode pads 311, 313, and 315 are in contact with the second electrode pads 415, 416, 419.

The base substrate 300 may be electrically connected to the device substrate 100 by a wafer-to-wafer bonding method. The second cavity area C2 may be a closed space formed by the base substrate 300 and the device substrate 100 being bonded using the bonding method.

The second cavity area C2 may be formed to have a step with respect to a surface of the base substrate 300. That is, a portion of the surface of the base substrate 300 may be etched to form an empty space, and the empty space may be the second cavity area C2. The second cavity area C2 is formed to correspond to an area in which the device pattern dp is formed on the device substrate 100 so that the second cavity area C2 serves to provide a space in which the device pattern dp can vibrate when the device pattern dp vibrates up, down, left, and right.

One or more second cavity areas C2 may be formed. Since the device pattern dp formed on the device substrate 100 may have a complicated shape and a plurality of areas in which the device pattern dp vibrates may be present, the one or more second cavity areas C2 may be formed to correspond to positions at which the device pattern dp vibrates.

When one or more second cavity areas C2 are formed, the cavity areas may be separated from one another by a second sealing wall 300s formed by the base substrate 300 and the device substrate 100.

The first TSVs 303 and 304 may be brought into contact with anchors 110 and 111 of the device substrate 100, respectively. The anchors 110 and 111 may serve to support electrodes or structures. In detail, the anchors 110 and 111 may operate as fixed lateral electrodes.

Further, the first TSV 305 may operate as a vertical electrode. An electric signal may be applied to the first TSV 305 to drive the device pattern dp thereabove. Similarly, an electrical signal may be applied through the anchors 110 and 111 to drive the device pattern dp. Alternatively, an electrical signal of the device pattern dp may be sensed using the first TSV 305 or be sensed through the anchors 110 and 111.

Referring to FIG. 1, the circuit board 400 may be disposed below the base substrate 300, and a integrated circuit 420 may be formed on the circuit board 400 and electrically connected to the first TSVs 303, 304, and 305 formed on the base substrate 300 to process the electric signal for the device pattern dp.

In detail, the second electrode pads 415, 416, and 419 may be electrically connected to a wiring line 418 and finally connected to an I/O terminal 417 outside the passivation film 320. The wiring line 418 is also partially insulated by the passivation film 320, and a portion of the wiring line 418 that is in contact with the I/O terminal 417 may be exposed to the outside of the passivation film 320. The I/O terminal 417 may be a terminal capable of inputting and outputting external electric signals.

The circuit board 400 may be formed to include one or more TSVs. The one or more TSVs may be arranged in a point symmetry structure with respect to the center of the circuit board 400. When the one or more TSVs are arranged in a point symmetry structure, physical pressure applied from the outside to the circuit board 400 may be uniformly dispersed.

The metal pads 203 and 204 and the solder contacts 205 and 206 may contain silicon. However, the present invention is not limited thereto. That is, the metal pads 203 and 204 and the solder contacts 205 and 206 may contain the same material, but the present invention is not limited thereto. The metal pads 203 and 204 may be brought into contact with the solder contacts 205 and 206 to bond the device substrate 100 and the cap substrate 200.

Unlike what is shown, the bonding method of the present invention may be variously modified and carried out. That is, as long as the base substrate 300 and the circuit board 400 can be electrically connected to each other, the bonding method may be modified and carried out in a form different from the shown. For example, a contact method including a solder ball may be possible. In this case, the metal pads 203 and 204 and the solder contacts 205 and 206 may contain a first material, and the solder ball may contain a second material.

Here, the first material may include, for example, silicon (Si). Silicon (Si) has a melting point of 1,410° C. The second material may include, for example, copper (Cu). Copper (Cu) has a melting point of 1,084° C.

That is, the first material has a higher melting point than the second material. As an example, the first material may be silicon (Si), nickel (Ni), cobalt (Co), iron (Fe), or the like. Nickel (Ni) has a melting point of 1,453° C., cobalt (Co) has a melting point of 1,495° C., and iron (Fe) has a melting point of 1,535° C.

Also, as an example, the second material may be copper (Cu), manganese (Mn), or the like. Manganese (Mn) has a melting point of 1,246° C.

Referring to FIG. 2, according to some embodiments of the present invention, the circuit board 400 may be placed above the cap substrate 200. In this case, the cap substrate 200, the device substrate 100, and the base substrate 300 may be flipped and brought into contact with an upper surface of the circuit board 400. That is, the cap substrate 200, the device substrate 100, and the base substrate 300 may be sequentially stacked on the circuit board 400.

As shown in FIG. 2, second electrode pads 415′, 416′, and 419′, a wiring line 418′, and an I/O terminal 417′ may be placed not on the circuit board 400 but on the base substrate 300. In detail, the second electrode pads 415′, 416′, and 419′, the wiring line 418′, and the I/O terminal 417′ may be formed on an upper surface of the flipped base substrate 300.

Also, the circuit board 400 may include a separate circuit I/O terminal 425. The circuit I/O terminal 425 may be electrically connected to the I/O terminal 417′ of the base substrate 300. In detail, the circuit I/O terminal 425 may be electrically connected to the I/O terminal 417′ of the base substrate 300 through a bonding wire W. To this end, the circuit board 400 may have a greater width than the base substrate 300.

Referring to FIGS. 1 to 5 again, the first TSV 303 may have a double structure. That is, the first TSV 303 may include first core areas 303a, 304a, and 305a, first insulating areas 303b, 304b, and 305b, first peripheral areas 303c, 304c, and 305c, and second insulating areas 303d, 304d, and 305d. Hereinafter, for convenience, the first core area 303a, the first insulating area 303b, the first peripheral area 303c, and the second insulating area 303d will be described as a reference.

The first core area 303a may be an area for outputting an electric signal provided from the device pattern dp to the outside or transmitting an electric signal provided from the outside to the device pattern dp. The first core area 303a may be doped silicon. However, the present invention is not limited thereto, and the first core area 303a may also be a metal.

The first insulating area 303b may be formed to surround the first core area 303a. That is, the first insulating area 303b may be of a hollow ring shape. A side surface of the first core area 303a may be fully insulated by the first insulating area 303b. An outer surface of the first core area 303a may be in direct contact with an inner surface of the first insulating area 303b. The first insulating area 303b may contain an insulator. The first insulating area 303b may contain, for example, a silicon oxide film or a silicon nitride film. However, the present invention is not limited thereto.

The first peripheral area 303c may surround the first insulating area 303b. That is, the first peripheral area 303c may be of a hollow ring shape. An outer surface of the first insulating area 303b may be in direct contact with an inner surface of the first peripheral area 303c. The first peripheral area 303c may be formed of doped silicon of the base substrate 300.

The second insulating area 303d may be formed to surround the first peripheral area 303c. That is, the second insulating area 303d may be of a hollow ring shape. A side surface of the first peripheral area 303c may be fully insulated by the second insulating area 303d. An outer surface of the first peripheral area 303c may be in direct contact with an inner surface of the second insulating area 303d. The second insulating area 303d may contain an insulator. The second insulating area 303d may contain, for example, a silicon oxide film or a silicon nitride film. However, the present invention is not limited thereto.

The second insulating area 303d may be surrounded by the base substrate 300. The base substrate 300 may contain doped silicon.

Referring to FIG. 6, the first TSV 303 may have parasitic capacitance because a dielectric is sandwiched between conductors in terms of structure. Such parasitic capacitance may generate parasitic noise, which causes inaccurate transmission of signals intended by a user.

A single insulating area being present corresponds to a single capacitor. However, according to some embodiments of the present invention shown in FIGS. 1 to 6, an insulating area being two-layered corresponds to two capacitors connected in series to each other.

That is, when the capacitance of a capacitor formed by the first insulating area 303b is referred to as C1 and the capacitance of a capacitor formed by the second insulating area 303d is referred to as C2, the total capacitance C0 of the two capacitors being connected in series is defined using the following equation:

$$\frac{1}{C 1} + \frac{1}{C 2} = \frac{1}{C 0} .$$

This may mean that C0 is smaller than C1 or C2 on the assumption that C1 and C2 are positive. That is, the second insulating area 303d being formed may mean that the parasitic capacitance is significantly reduced.

As the parasitic capacitance decreases, parasitic noise of a signal delivered through the first TSV 303 may decrease. Thus, it is possible to increase the precision and operation speed of the MEMS sensor according to some embodiments of the present invention.

Referring to FIGS. 3 and 4 again, a plurality of TSVs are placed on a substrate, respectively. The base TSV shown in FIGS. 3 and 4 may be composed of a single conductor and a surrounding insulator. The double TSV shown in FIGS. 3 and 4 may be composed of a single-layered insulator surrounding the base TSV.

The arrangement of such TSVs may be determined appropriately according to the spaces of the device substrate 100 and the base substrate 300. That is, a general TSV may be formed in a region that is too narrow to form a double TSV, and a double TSV may be formed in a region that has available space.

The TSVs shown in FIGS. 3 and 4 may include a supply TSV Vi for supplying power from the outside to the inside and an output TSV Vo for outputting signals from the inside to the outside.

An electric signal with a relatively higher voltage may be transmitted through the supply TSV Vi for supplying power than through the output TSV Vo for outputting signals. Accordingly, parasitic signal noise due to parasitic capacitance may be relatively increased.

The MEMS sensor according to some embodiments of the present invention may optimize the efficiency of parasitic noise reduction and the utilization of space because the supply TSV Vi is preferentially formed as the double TSV and the output TSV Vo is formed as the double TSV depending on space allowed subsequently. Accordingly, it is possible to maximize the operation performance and efficiency of the MEMS sensor.

In particular, since the gyro sensor GP of FIG. 4 has many TSVs that transmit an electric signal with a relatively high voltage, it is possible to greatly increase the efficiency of a double TSV or a TSV with a three- or more-layered insulating area. That is, the parasitic noise of supplied power and the parasitic noise of an output signal are greatly reduced, and it is possible to provide a gyro MEMS sensor having high precision, high speed, and low power consumption.

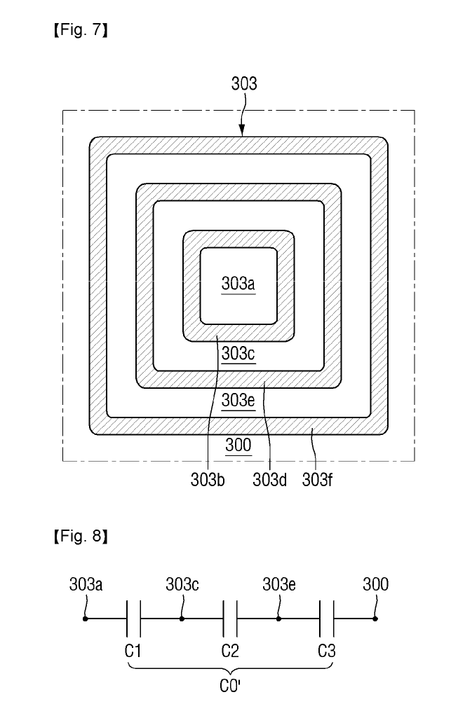

Hereinafter, a MEMS sensor according to some embodiments of the present invention will be described with reference to FIGS. 7 and 8.

FIG. 7 is a plane-sectional view for describing a TSV of a MEMS sensor according to some embodiments of the present invention, and FIG. 8 is an equivalent circuit diagram for describing the TSV of FIG. 7 in detail.

The TSV of FIG. 7 may further include a second peripheral area 303e and a third insulating area 303f.

The second peripheral area 303e may surround the second insulating area 303d. That is, the second peripheral area 303e may be of a hollow ring shape. An outer surface of the second insulating area 303d may be in direct contact with an inner surface of the second peripheral area 303e. The second peripheral area 303e may be formed of doped silicon of the base substrate 300.

The third insulating area 303f may be formed to surround the second peripheral area 303e. That is, the third insulating area 303f may be of a hollow ring shape. A side surface of the second peripheral area 303e may be fully insulated by the third insulating area 303f. An outer surface of the second peripheral area 303e may be in direct contact with an inner surface of the third insulating area 303f. The third insulating area 303f may contain an insulator. The third insulating area 303f may contain, for example, a silicon oxide film or a silicon nitride film. However, the present invention is not limited thereto.

The third insulating area 303f may be surrounded by the base substrate 300. The base substrate 300 may contain doped silicon.

Two insulating areas being present as shown in FIGS. 5 and 6 correspond to two capacitors. However, according to some embodiments of the present invention shown in FIGS. 7 and 8, an insulating area being three-layered corresponds to three capacitors connected in series to one another.

That is, when the capacitance of a capacitor formed by the first insulating area 303b is referred to as C1, the capacitance of a capacitor formed by the second insulating area 303d is referred to as C2, and the capacitance of a capacitor formed by the third insulating area 303f is referred to as C3, the total capacitance C0′ of the three capacitors being connected in series is defined using the following equation:

$$\frac{1}{C 1} + \frac{1}{C 2} + \frac{1}{C 3} = \frac{1}{C {0}^{′}} .$$

This may mean that C0′ is smaller than C1, C2, or C3 on the assumption that C1, C2, and C3 are positive. That is, the third insulating area 303f being additionally formed may mean that the parasitic capacitance is significantly reduced.

As the parasitic capacitance decreases, parasitic noise of a signal delivered through the first TSV 303 may decrease. Thus, it is possible to increase the precision and operation speed of the MEMS sensor according to some embodiments of the present invention.

Referring to FIGS. 1 to 8 of the present invention, it is shown that the insulating area is two-layered or three-layered, but the present invention is not limited thereto. That is, the insulating area may be four- or more-layered as long as space is allowed.

A MEMS sensor according to some embodiments of the present invention will be described below with reference to FIGS. 3, 4, and 9.

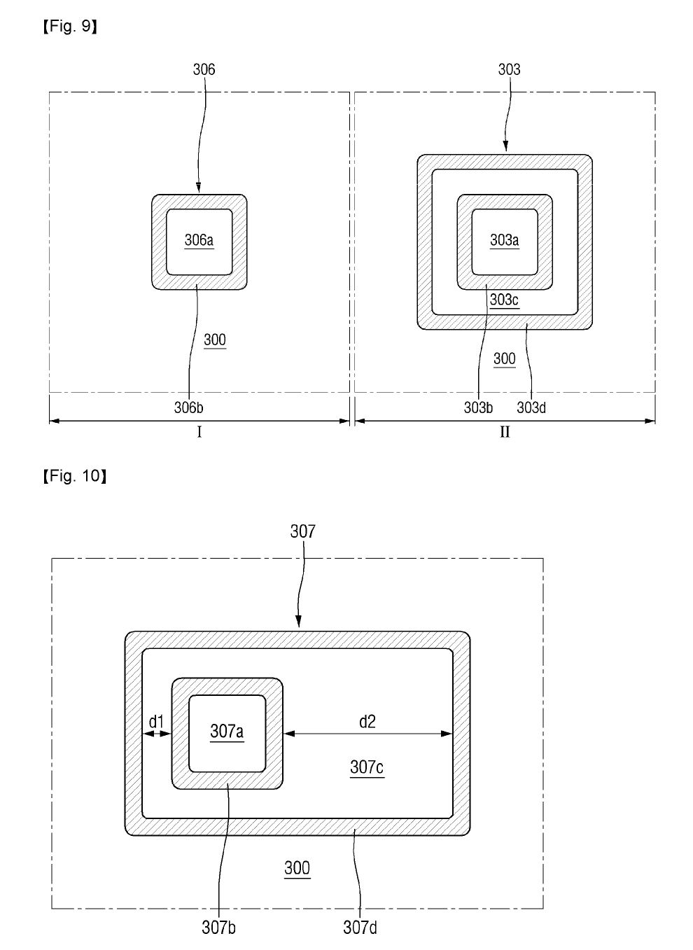

FIG. 9 is a plane-sectional view for describing a TSV of a MEMS sensor according to some embodiments of the present invention.

Referring to FIG. 9, the base substrate 300 may include a first area I and a second area II. The first area I and the second area II may be adjacent to or spaced apart from each other. The first area I and the second area II may include a second TSV 306 and a first TSV 303, respectively.

The first TSV 303 is the same as that described in FIG. 5.

The second TSV 306 may include a second core area 306a and a fourth insulating area 306b. That is, the insulating area of the second TSV 306 may be one layer smaller than that of the first TSV 303.

The second TSV 306 may be formed according to a spatial margin of the base substrate 300. That is, the second TSV 306 having a single-layered insulating area may be included together with the first TSV 303 in order to prevent collision with another element of the base substrate 300 or another element of the device substrate 100 overlapping the base substrate 300.

Referring to FIGS. 3 and 4, it can be seen that some TSVs are shown in the form of the second TSV 306 with a single insulating area.

A MEMS sensor according to some embodiments of the present invention will be described below with reference to FIG. 10.

FIG. 10 is a plane-sectional view for describing a TSV of a MEMS sensor according to some embodiments of the present invention.

Referring to FIG. 10, the MEMS sensor according to some embodiments of the present invention may have a third TSV 307 included in the base substrate 300. The third TSV 307 may include a third core area 307a, a fifth insulating area 307b, a third peripheral area 307c, and a sixth insulating area 307d.

The third core area 307a and the fifth insulating area 307b are similar to the first core area 303a and the first insulating area 303b of FIG. 5, and thus redundant description thereof will be omitted for convenience.

The third peripheral area 307c may surround the fifth insulating area 307b. The sixth insulating area 307d may surround the third peripheral area 307c. The third peripheral area 307c may have a non-uniform width. That is, a distance d1 or d2 between the sixth insulating area 307d and the fifth insulating area 307b may vary depending on direction.

That is, even though the distance between the insulating areas is not constant, the parasitic capacitance decreases; however, there is a difference in the degree of decrease of the parasitic capacitance in each direction. Accordingly, the position of the insulating area and the size of the peripheral area may be adjusted appropriately according to a spatial margin of the base substrate 300.

A MEMS sensor according to some embodiments of the present invention will be described below with reference to FIGS. 3, 4, and 11.

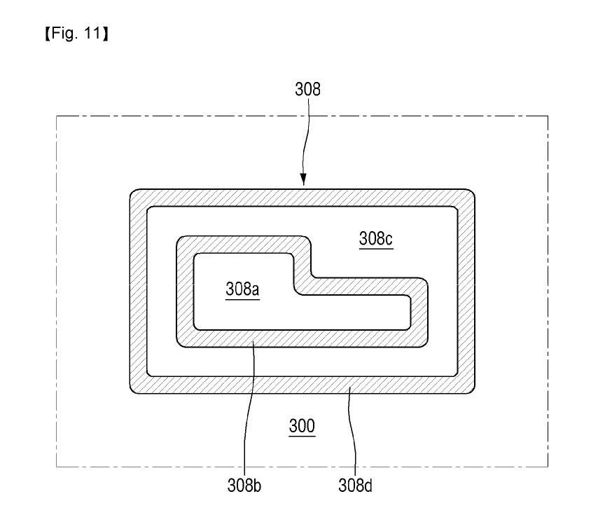

FIG. 11 is a plane-sectional view for describing a TSV of a MEMS sensor according to some embodiments of the present invention.

Referring to FIG. 11, the MEMS sensor according to some embodiments of the present invention may have a fourth TSV 308 included in the base substrate 300. The fourth TSV 308 may include a fourth core area 308a, a seventh insulating area 308b, a fourth peripheral area 308c, and an eighth insulating area 308d.

The shape of the fourth core area 308a may be defined by the seventh insulating area 308b, and the shape of the fourth peripheral area 308c may be defined by the seventh insulating area 308b and the eighth insulating area 308d. The seventh insulating area 308b may have a different shape from the eighth insulating area 308d. Here, conceptually, the different shape may include neither similar figures nor congruent figures.

That is, the MEMS sensor according to some embodiments of the present invention has no limitations on the shape of an external area as long as it is possible for the shape to decrease parasitic capacitance through a two- or more-layered insulating area, that is, to fully surround an internal area. Accordingly, the shape of the external area may be formed in a free shape by a processing space margin and a design rule.

Referring to FIGS. 3 and 4, it can be seen that some double TSVs are shown in the form of the fourth TSV 308 shaped differently from the base TSV.

A MEMS sensor according to some embodiments of the present invention will be described below with reference to FIGS. 3, 4, and 12.

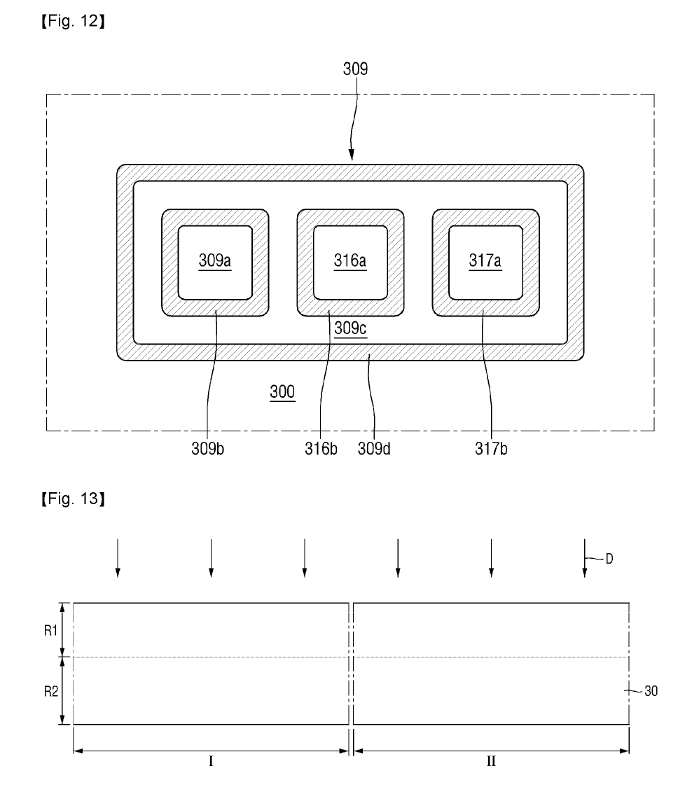

FIG. 12 is a plane-sectional view for describing a TSV of a MEMS sensor according to some embodiments of the present invention.

Referring to FIG. 12, the MEMS sensor according to some embodiments of the present invention may have a fifth TSV 309 included in the base substrate 300. The fifth TSV 309 may include fifth core areas 309a, 316a, and 317a, ninth insulating areas 309b, 316b, and 317b, a fifth peripheral area 309c, and a tenth insulating area 309d.

As shown, a plurality of fifth core areas 309a, 316a, and 317a and a plurality of ninth insulating areas 309b, 316b, and 317b may be present. However, the fifth peripheral area 309c and the tenth insulating area 309d may be a single area that surrounds the plurality of fifth core areas 309a, 316a, and 317a and the plurality of ninth insulating areas 309b, 316b, and 317b.

The fifth core areas 309a, 316a, and 317a may transmit respective signals. Accordingly, parasitic capacitance generated in each of the fifth core areas 309a, 316a, and 317a may be independently decreased even by the single area composed of the fifth peripheral area 309c and the tenth insulating area 309d.

Accordingly, it is possible to reduce parasitic noise by surrounding a plurality of core areas with a single peripheral area according to a processing spatial margin and a design rule.

Referring to FIGS. 3 and 4, it can be seen that a single double TSV is shown in the form of the fifth TSV 309 corresponding to the plurality of base TSVs.

A method of manufacturing a MEMS sensor according to some embodiments of the present invention will be described below with reference to FIGS. 13 to 17. Descriptions overlapping with those of the MEMS sensor shown in FIGS. 1 to 12 will be simplified or omitted.

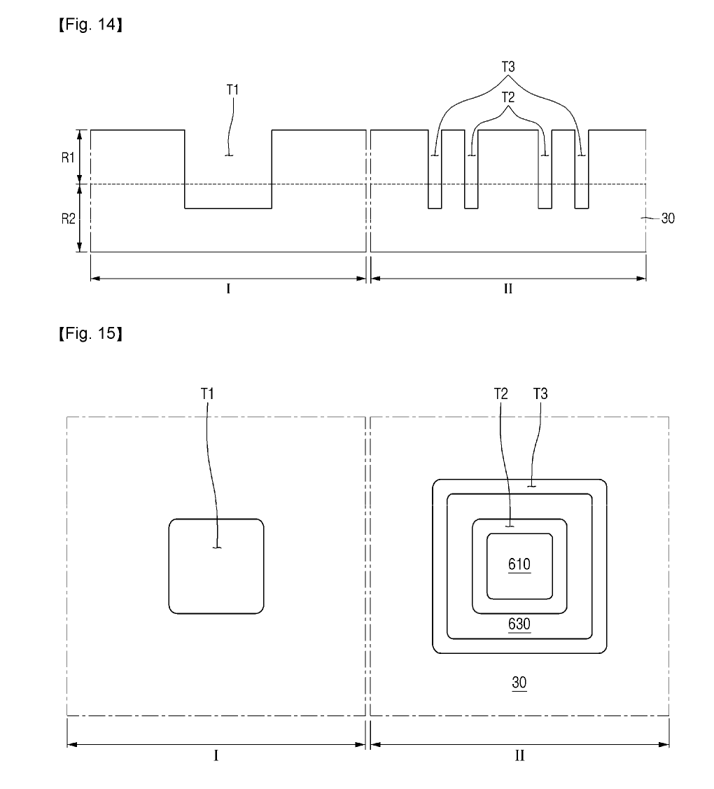

FIGS. 13 to 17 are intermediate views for describing a method of manufacturing a MEMS sensor according to some embodiments of the present invention. FIG. 15 is a view showing a plan view of an upper surface of FIG. 14.

Referring to FIG. 13, a pre-base substrate 30 is doped.

The pre-base substrate 30 may be processed into the base substrate later. The pre-base substrate 30 may include an available area R1 and a removal area R2 depending on thickness. The available area R1 may be an area to be processed and then used later, and the removal area R2 may be a part to be removed later. The removal area R2 may have a greater thickness than the available area R1, but the present invention is not limited thereto.

The pre-base substrate 30 may be a silicon substrate, but the present invention is not limited thereto. The pre-base substrate 30 may be another semiconductor substrate such as germanium.

The pre-base substrate 30 may include a first area I and a second area II. The first area I and the second area II may be adjacent to or spaced apart from each other.

The pre-base substrate 30 may be doped as a whole to have increased conductivity. Thus, a core area may be formed just by forming an insulating area and performing device separation later.

Subsequently, referring to FIGS. 14 and 15, a first trench T1, a second trench T2, and a third trench T3 are formed.

The first trench T1 may be formed in the first area I. The first trench T1 may be a part where the core area is to be formed later. In FIG. 15, a horizontal section is shown as a quadrangle, but the present invention is not limited thereto.

The second trench T2 and the third trench T3 may be formed in the second area II. The second trench T2 and the third trench T3 may be annular trenches. That is, a sixth core area 610 may be defined in the second trench T2 by the second trench T2. Also, a sixth peripheral area 630 may be defined between the second trench T2 and the third trench T3.

The first trench T1, the second trench T2, and the third trench T3 may be formed deeper than the available area R1. That is, the first trench T1, the second trench T2, and the third trench T3 may be formed up to a portion of an upper portion of the removal area R2.

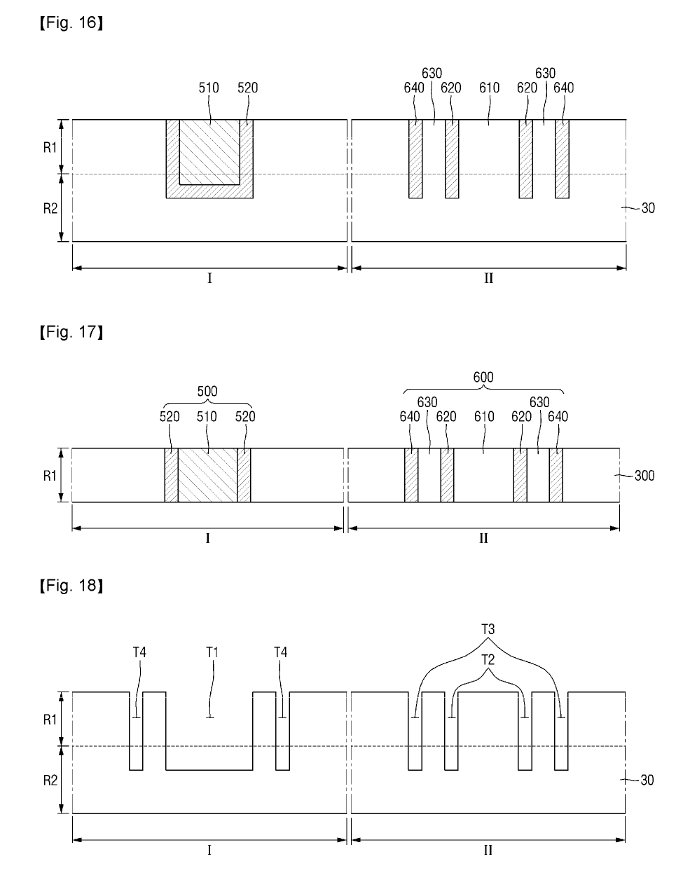

Subsequently, referring to FIG. 16, the first trench T1, the second trench T2, and the third trench T3 are filled.

In the first area I, the first trench T1 may be filled with a seventh core area 510 and a thirteenth insulating area 520. The thirteenth insulating area 520 may be conformally formed along a side surface and a bottom surface of the first trench T1. The thirteenth insulating area 520 may contain an insulator, for example, at least one of a silicon oxide film and a silicon nitride film. However, the present invention is not limited thereto.

The seventh core area 510 may be formed on the thirteenth insulating area 520 to fully fill the first trench T1. The seventh core area 510 may contain a conductor. For example, the seventh core area 510 may contain at least one of a metal and doped polysilicon.

In the second area II, the second trench T2 and the third trench T3 may be fully filled with an insulator. Thus, an eleventh insulating area 620 and a twelfth insulating area 640 may be formed.

Subsequently, referring to FIG. 17, the removal area R2 is removed.

The removal area R2 placed below the available area R1 may be removed. The removal area R2 may be removed using chemical-mechanical polish (CMP), but the present invention is not limited thereto. The pre-base substrate 30 may become the base substrate 300 by the removal area R2 being removed.

As the removal area R2 is removed, the first trench T1, the second trench T2, and the third trench T3 may pass through the base substrate 300. That is, lower surfaces of the seventh core area 510 and the thirteenth insulating area 520 may be exposed to the outside, and a seventh TSV 500 including the seventh core area 510 and the thirteenth insulating area 520 may be completed in the first area I.

In the second area II, lower surfaces of the sixth core area 610, the eleventh insulating area 620, the sixth peripheral area 630, and the twelfth insulating area 640 may be exposed to the outside, and a sixth TSV 600 including the sixth core area 610, the eleventh insulating area 620, the sixth peripheral area 630, and the twelfth insulating area 640 may be completed.

In FIGS. 13 to 17, the seventh TSV 500 of the first area I and the sixth TSV 600 of the second area II have been described as being formed through the same process, but the present invention is not limited thereto. That is, the sixth TSV 600 and the seventh TSV 500 may be formed in each area at different times.

The seventh core area 510 of the seventh TSV 500 may be doped polysilicon or metal, and the sixth core area 610 of the sixth TSV 600 may be doped polysilicon. That is, the sixth core area 610 and the seventh core area 510 may be formed of different materials or the same material.

In FIGS. 13 to 17, the TSV of the MEMS sensor may include the seventh TSV 500 of the first area I and the sixth TSV 600 of the second area II which are formed by different processes.

For the second area II, it is possible to complete the TSV just by merely forming an insulating area without needing to form a new core area, and it is also possible to minimize parasitic noise by forming multiple insulating areas and then reducing parasitic capacitance by the above-described method.

However, when the method of forming a TSV in the second region II is performed, formation of a TSV may be difficult due to process limitations when the scale of the TSV is reduced. On the contrary, when the method of forming the TSV in the first region I is performed, a relatively small TSV may be effectively formed.

Therefore, the MEMS sensor according to some embodiments of the present invention may form an optimal TSV structure, considering the importance of parasitic signal noise reduction and process limitations on the same base substrate 300.

A method of manufacturing a MEMS sensor according to some embodiments of the present invention will be described below with reference to FIGS. 13 and 18 to 21. Descriptions overlapping with those of the MEMS sensor and the manufacturing method thereof shown in FIGS. 1 to 17 will be simplified or omitted.

FIGS. 18 to 21 are intermediate views for describing a method of manufacturing a MEMS sensor according to some embodiments of the present invention. FIG. 19 is a view showing a plan view of an upper surface of FIG. 18.

Referring to FIGS. 13, 18, and 19, a fourth trench T4 may be further formed in the first area I of the doped pre-base substrate 30.

The fourth trench T4 may be an annular trench that surrounds the first trench T1. As the fourth trench T4 is formed, the seventh TSV 500 of the first area I may become a double TSV later.

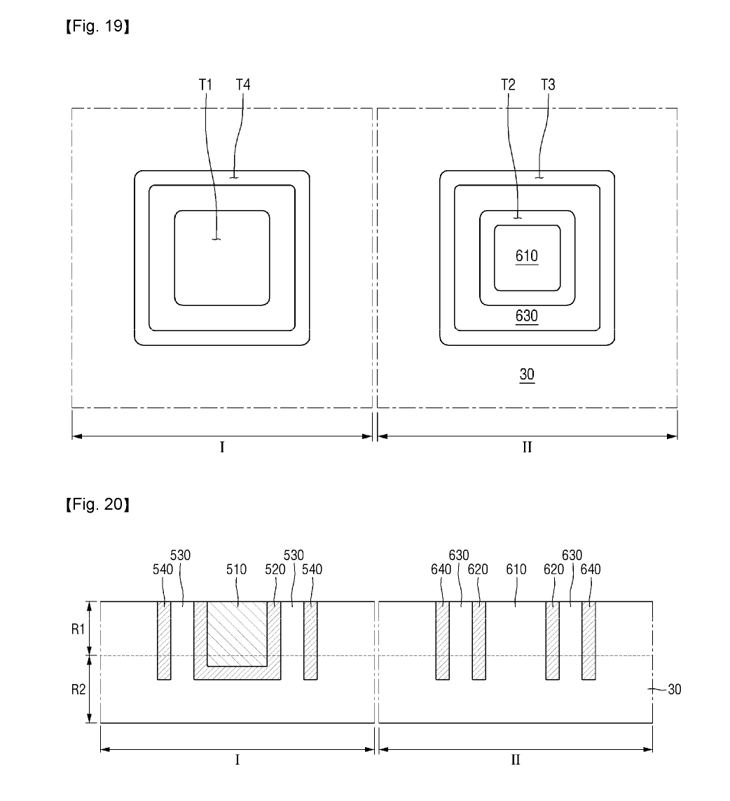

Subsequently, referring to FIG. 20, the first trench T1, the second trench T2, the third trench T3, and the fourth trench T4 are filled.

The fourth trench T4 may be filled with an insulating material. That is, a fourteenth insulating area 540 may be formed in the fourth trench T4. As the fourteenth insulating area 540 is formed, a seventh peripheral area 530 may be defined between the fourteenth insulating area 540 and the thirteenth insulating area 520. The fourteenth insulating area 540 may contain, for example, at least one of a silicon oxide film and a silicon nitride film.

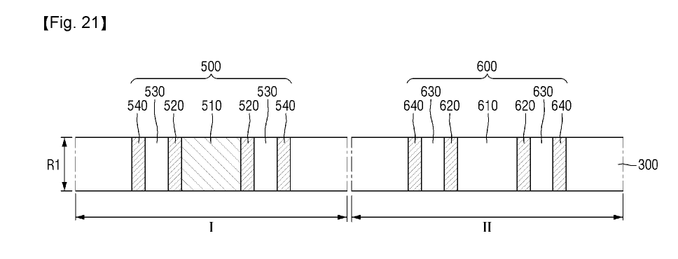

Subsequently, referring to FIG. 21, the removal area R2 is removed.

As the removal area R2 is removed, the first trench T1, the second trench T2, the third trench T3, and the fourth trench T4 may pass through the base substrate 300. That is, lower surfaces of the seventh core area 510, the thirteenth insulating area 520, the seventh peripheral area 530, and the fourteenth insulating area 540 may be exposed to the outside, and a seventh TSV including the seventh core area 510 and the thirteenth insulating area 520 may be completed in the first area I.

The MEMS sensor shown in FIGS. 18 to 21 may minimize parasitic noise of the TSV in the first area I while taking advantages of the MEMS sensor shown in FIGS. 13 to 17. Accordingly, it is possible to manufacture an enhanced MEMS sensor capable of achieving two goals, that is, minimization of processing DOF and minimization of parasitic noise.

Although the embodiments of the present invention have been described with reference to the accompanying drawings, it will be understood by those skilled in the art that the present invention may be embodied in other specific forms without departing from the spirit or essential characteristics thereof. It is therefore to be understood that the above-described embodiments are illustrative in all aspects and not restrictive.

What is claimed is:

1. A microelectromechanical systems (MEMS) sensor comprising:
a device substrate on which a device pattern is formed;
a cap substrate disposed above the device substrate, the cap substrate comprising a first cavity area;
a base substrate disposed below the device substrate;
a first through-silicon via formed through the base substrate, the first through-silicon via comprising: a first core area for outputting a first electric signal provided from the device pattern to the outside or transmitting a second electric signal provided from the outside to the device pattern; a first insulating area surrounding an outer surface of the first core area; a first peripheral area surrounding an outer surface of the first insulating area and disallowing delivery of electric signals other than the first electric signal and the second electric signal; and a second insulating area surrounding an outer surface of the first peripheral area; and
a circuit board electrically connected to the first through-silicon via to process electric signals for the device pattern.

2. The MEMS sensor of claim 1, further comprising a second through-silicon via formed through the base substrate and spaced apart from the first through-silicon via, the second through-silicon via comprising:
a second core area for outputting an electric signal provided from the device pattern to the outside or transmitting an electric signal provided from the outside to the device pattern; and
a third insulating area surrounding an outer surface of the second core area.

3. The MEMS sensor of claim 2, further comprising:
a third through-silicon via formed through the base substrate and spaced apart from the first through-silicon via and the second through-silicon via, the third through-silicon via comprising: a third core area for outputting an electric signal provided from the device pattern to the outside or transmitting an electric signal provided from the outside to the device pattern; and a fourth insulating area surrounding an outer surface of the third core area; and
a fifth insulating area surrounding the second through-silicon via and the third through-silicon via.

4. The MEMS sensor of claim 2, further comprising:
a second peripheral area surrounding an outer surface of the third insulating area; and
a fourth insulating area surrounding an outer surface of the second peripheral area,
wherein the first core area has the same shape as the second core area and the first peripheral area has a different shape from the second peripheral area.

5. The MEMS sensor of claim 4, wherein the first core area has the same size as the second core area and the first peripheral area has a different size from the second peripheral area.

6. The MEMS sensor of claim 2,
wherein the first through-silicon via supplies power from the outside to the device pattern, and
wherein the second through-silicon via outputs a signal from the device pattern to the outside.

7. The MEMS sensor of claim 1, wherein the first through-silicon via further comprises:
a third peripheral area surrounding an outer surface of the second insulating area; and
a sixth insulating area surrounding an outer surface of the third peripheral area.

8. The MEMS sensor of claim 7, wherein the second insulating area has a different shape from the sixth insulating area.

9. The MEMS sensor of claim 1,
wherein the base substrate comprises an x-axis area, a y-axis area, and a z-axis area, and
wherein the first through-silicon via is disposed in the x-axis area in the same form as, but perpendicularly to, that in the y-axis area.

10. The MEMS sensor of claim 1, wherein the circuit board is disposed below the base substrate and electrically connected to a lower surface of the first through-silicon via.

11. The MEMS sensor of claim 1, wherein the circuit board is disposed above the cap substrate and connected to the first through-silicon via by wire bonding.

12. A method of manufacturing a microelectromechanical systems (MEMS) sensor, the method comprising:
doping a base substrate as a whole;
forming, in the base substrate, a first annular trench, a second annular trench surrounding the first annular trench, a first core area defined by the first annular trench, and a first peripheral area defined by the first annular trench and the second annular trench;
forming a first insulating area and a second insulating area by filling the first annular trench and the second annular trench with an insulating material, respectively; and
polishing a lower surface of the base substrate and separating the first core area from the first peripheral area to form a first through-silicon via including the first core area, the first insulating area, the first peripheral area, and the second insulating area.

13. The method of claim 12, further comprising:
forming a pillar-type trench in the base substrate;
forming an insulating film on an inner wall of the trench; and
forming a conductive film for filling the trench on the insulating film to form a second through-silicon via including the insulating film and the conductive film,
wherein the second through-silicon via is spaced apart from the first through-silicon via.

14. The method of claim 13, further comprising forming a through-insulating film that surrounds the second through-silicon via and passes through the base substrate.

15. The method of claim 12, wherein the forming of the first annular trench and the second annular trench further comprises forming a third annular trench surrounding the second annular trench and a second peripheral area defined by the second annular trench and the third annular trench.
